(19) United States
(12) Patent Application Publication
(10) Pub. No.: US 2009/0211566 A1
(43) Pub. Date: Aug. 27, 2009

(54) Tracking System for Wave Sources

(76) Inventor: Roberto Battiston, Perugia (IT)

Correspondence Address: KATTEN MUCHIN ROSENMAN LLP, 575 MADISON AVENUE, NEW YORK, NY, 10022-2585, US

(21) Appl. No.: 12/391,381

(22) Filed: Feb. 24, 2009

(30) Foreign Application Priority Data
Feb. 26, 2008 (IT) MI2008A000300

(51) Int. Cl. F24J 2/38; H01L 31/042

(52) U.S. Cl. 126/573; 136/246

(57) ABSTRACT

A tracking system for wave sources comprises a fixed panel (1) for the support of at least one receiving element (2) of incoming waves, which can be oriented with respect to the panel (1).

The invention refers to a tracking system for wave sources, in particular sources of light waves generated by solar rays.

As it is well known, the photovoltaic systems use the solar energy to produce electricity or other forms of energy.

A recent development of the research on photovoltaic systems has evolved towards the so-called “concentrated” photovoltaic systems which exploit a concentrator device to intercept the solar light rays and subsequently concentrate them on a photovoltaic cell of size inversely proportional to the concentration factor of the device.

Concentrating photovoltaic systems provide an higher performance if compared to traditional photovoltaic planar systems.

On the other hand, however, known concentrating devices have significant sizes and require continuous movement along the trajectory which maximize the exposure to the solar radiation (so-called “solar tracking”) to obtain the best system performances: this displacement must also occur in the event of adverse weather.

For all these reasons, the mechanical movements are very heavy, of significant weight and size and together the significant weight and sizes of the concentrating devices, can make not possible the installation of photovoltaic systems on building roofs and on non horizontal surfaces requiring a preferred placing in flat and uninhabitated areas.

The object of the present invention is to provide a tracking system for wave sources with improved tracking means to overcome the drawbacks of the prior art.

The object above is achieved by the tracking system for wave source according to claim 1.

The system, according to the invention, achieves the following advantages with respect to the prior art:
although complex it has a lower volume and greater compactness;
it is suitable for installation in different environments (even in not flat residential areas and over buildings);
it is not very vulnerable to adverse weather conditions
the moving means have simple implementation;
the moving means have low costs.

The features and further advantages of the invention will be clear from the following description, of an embodiment thereof provided only as way of non limitative example with reference to the attached drawings.

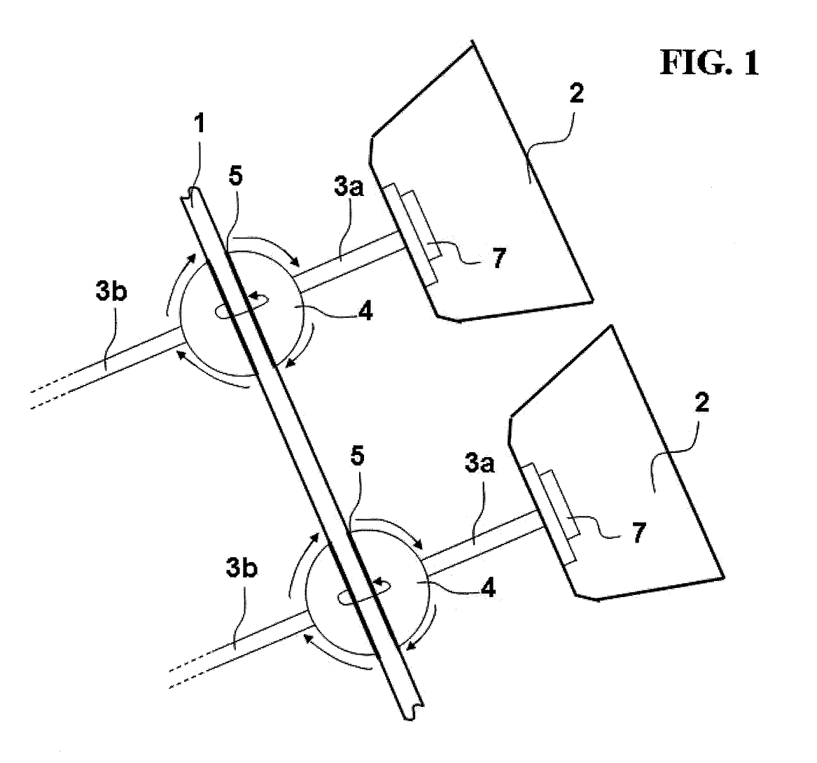

FIG. 1 shows schematically a side view of a portion of a tracking system for wave sources according to the invention.

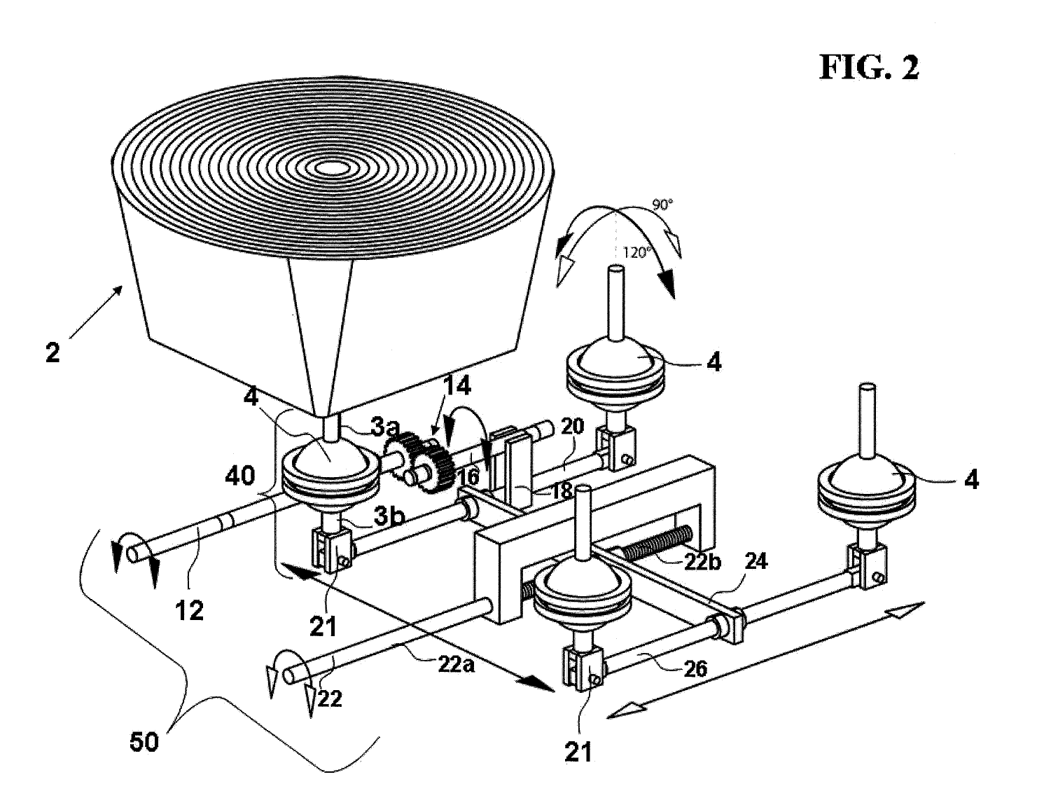

FIG. 2 shows a preferred embodiment of the moving means according to the invention.

With reference to the figures, a tracking system according to the invention comprises a panel 1 acting as a support for waves receiving or emitting elements 2; in the preferred embodiment, the elements 2 are receiving elements, in particular photovoltaic elements, and in FIG. 1 are shown, as way of example, only two photovoltaic elements 2, receiving waves generated by solar radiations and represented schematically in the form of a small tray (panel 1 is omitted, for simplicity, in FIG. 2).

In a real configuration, the number of photovoltaic elements 2 may vary depending on the surface to be covered and the amount of energy to be provided.

Systems for domestic energy supply which require installations on buildings should be smaller than energy supply systems for business or industrial areas installable in wider free areas or not densely populated areas, which can reach overall dimensions up to several hundred square meters.

The elements 2 are positioned at the top of a supporting rod 3 to which are constrained through suitable locking means, for example, a threaded ring nut 7 placed on the bottom of the photovoltaic element 2, which is screwed to the end of the supporting rod 3 passing through the bottom of the element itself.

The supporting rod 3, on the side not facing the photovoltaic element 2 is also passing through the axis of a spherical joint 4 housed in a suitable hole located on panel 1.

In the preferred embodiment, orienting means 40 comprise spherical joints 4, which are rotatably associated to the panel 1 through bearings not shown in the figures as well as supporting rods 3. Each sphere, in the same number of photovoltaic elements 2, is housed in one of said holes and is free to rotate on itself while, on the contrary, it is locked in translation on the plane of the panel 1 by the corresponding hole wherein is housed, as well along any other plane, through two adjacent ring nuts 5 adjacent to the fixed panel 1, one inferiorly and the other superiorly, and constrained to each other by means of suitable through bolts or pass through screws.

The supporting rod 3 is, therefore, composed by a first part 3a, located superiorly with respect to the panel 1 and responsible for the connection between each photovoltaic element 2 and its corresponding spherical joint 4, and a second part 3b, located inferiorly with respect to the panel 1 and responsible for the connection of the spherical joint 4 to the moving means 50 responsible for the rotation of the sphere 4 itself.

In general, one may consider the assembly of orienting means 40 and of the moving means 50 as waves tracking means.

According to the invention, in the course of the day, the tracking of solar rays is achieved by keeping fixed the panel 1 while orienting only the photovoltaic elements 2 in the direction of the solar rays.

More specifically, means for determining the orientation, namely known light sensors, detect along the course of the day the direction of maximum amplitude of the wave front and, through a suitable interface, transmit to the moving means 50 suitable commands to drive two stepper motors which, through a set of interconnections and joints, are connected to each spherical joint 4. The motors transmit a rotary motion to the spherical joints 4 and, consequently, to the photovoltaic elements 2; the motors operate along perpendicular directions generating a synchronous rotation of the spherical joints 4, and, correspondingly, of all the elements 2 housed on the support panel 1.

Other means for determining the orientation include means for a pre-planned processing of the panels orientation, for example a processing dependent on the different hours of the day taking into account the different direction of the incoming waves.

Such means are, in this case, responsible for the transmission, through a suitable interface, of suitable commands to the moving means 50 to actuate the two stepper motors.

Each stepper motor moves a set of elements 2 synchronously.

With reference to FIG. 2, one can appreciate the details of the moving means 50, according to a preferred embodiment of the invention. Of course, the structure may change without affecting the object of the invention.

A first rotating rod 12 is responsible for the transmission of the rotation movement, provided by one of the stepper motors, to a gear system 14 which transmits the rotary motion to a second rotating rod 16.

A pair of intermediate controls 18 constrains the second rotating rod 16 to an third rod 20 which holds a first pair of spherical joints 4 and their corresponding elements 2.

At the ends of the third rod 20 are associated supporting rods 3 through joints 21 which allow for the following movements of the rod 3 with respect to the third rod 20:

(a) tilting, exclusively in the plane generated by the shaft 20 and the rod 3 itself.

(b) rotation together with the third shaft 20

Following the rotation of the second rod 16, the supporting rod 3 rotates together with the third rod 20 leading to a consequent rotation of the sphere 4 and of the element 2.

A fourth rotating rod 22 comprises a first smooth portion 22a and a second threaded portion 22b.

The rotation of the fourth rod 22 actuated by the second stepper motor determines a screwing of the portion 22b, by means of a suitable threaded hole, on to a crossbar 24 limited in sliding at its ends to the third rod 20 and to a fifth rod 26 holding a second pair of spherical joints 4 and their corresponding elements 2.

The screwing of the portion 22b in to the threaded hole of the cross bar 24 determines a shift of the third rod 20 and of the fifth rod 26 along the respective axes, causing, in the first case, the movement of the rod labeled (a) and in the second case an identical movement, but made with respect to the fifth rod 26.

In substance, the sphere 4 rotates along two axes with mutually orthogonal directions, a first axis lying in the plane of the support 1 (direction substantially horizontal) and a second axis orthogonal to the first (direction substantially vertical). The resulting angular motion of the photovoltaic elements 2 can reach, in the vertical plane, up to 90 degrees and, in the horizontal plane, up to 120 degrees without adjacent elements interfere each other.

The mechanical design has been optimized considering the movement of the sun and a photovoltaic type of application, although other applications are possible.

The angular intervals correspond, with a good approximation, to the motion of the sun during the day, so this mechanism is suitable to handle an array of concentrated photovoltaic elements which must all be accurately pointed toward the sun all along the day, without the need to rotate the whole panel 1.

The angular range that can be spanned by this movement depends on the ratio between the diameter of the spherical joint 4 and the diameter of the support rod 3. A large diameter sphere can achieve larger angular excursions. The system can therefore be sized in accordance with specific environmental requirements that may require a larger span of the movement of the elements 2.

The movement of the elements 2 allow the following of a source producing a plane wave (light, sound, radio etc..) that, instead of using a single, suitable shaped, receiving panel, for example a parabolic disk shaped moved in order to be always perpendicular to the source, makes use of a large number of receiving elements each able to position perpendicularly to the source, without the need of moving the whole receiving panel.

This approach is very useful in case of large receiving structures, since with this mechanism the movement of a large structure can be replaced with the movement of many small structures.

Beneficial aspects of invention concern installation, the moving mechanics and the system mechanics highlighted in the following.

The common support plane can be oriented as needed. For example, it can be mounted on vertical walls, sloping roof, in a position (almost) horizontal: in all cases an array of photovoltaic sensors, also of large size (square meters), can be maintained perpendicular to the sun without the need to move the whole panel but only moving synchronously all the receiving members.

The movement allows for improved solar energy utilization than in the case of planar fixed panels, with a gain of approximately 20-30% in the number of produced KWh.

The mechanical part moving means 50 can be protected within an internal, closed volume, protected from the weather to ensure long term operation; this is a very important feature for system operating in dusty or desert areas.

Moreover, the complexity of the moving means capable of orienting small sized elements is very low with respect to that needed for moving whole receiving panels.

From what described so far, it has to be understood the operating of the system in its complexity.

Due to the emission of solar rays, known sensors detect along the day the direction of the maximum intensity of the solar radiation wave front and, through suitable software interfaces, transmit to the moving means 50 suitable commands to move the spheres 4 and, consequently, the photovoltaic elements 2 towards the detected directions.

Elements 2 rotate synchronously along two possible mutually orthogonal axes tracking the most intense wave front, without any movement of the supporting panel, to which the elements are constrained through supporting rods.

Another system feature is that elements 2 may be designed to be easily replaced and secured to the support rod through suitable interfaces such as bayonet or screw mechanism, comprising internally at least two power lines and the corresponding electrical contacts connected to wires passing in the inner part of the support rod 3 and in turn mutually connected below the support 1 in an area protected by the weather.

It is sufficient to develop a fastening interface coupling the photovoltaic element to the supporting rods.

The element 2, in this case would function as a “solar lamp” namely, a light bulb producing energy from light instead of using energy to produce light.

The solar lamp can be any type of concentrating (or non concentrating) photovoltaic element, such as those produced by the following companies: Amonix, Concentrix Solar GmbH, WHITFIELD SOLAR, Entec, Guascor, Solar Systems Pty, Spectrolab Inc., Whitfield Solar, Angelantoni Industrie spa etc.

The idea of the solar lamp is based on the possibility of separating the solar light tracking from the solar photovoltaic element itself, achieving the following advantages:
the individual element can be easily repaired or replaced;
the photovoltaic element can be replaced without changing the tracking system, which can remain installed independently;
the phases of installation of the tracking systems, connection to the power network and installation of the solar lamp can be performed independently of each other.
an additional and important advantage is that the replaceability of the elements 2 can be used both with reference to the fixed panels 1 of the invention, as well as with reference to known orientable panels, provided that they are properly segmented to be of the right size as the elements 2 of the present invention.

The mechanism for synchronous movement of this invention, also applies to the case of the synchronous movement of mirroring elements arranged in order to reproduce a spherical or a parabolic mirror, as for example in the case of a Fresnel mirror formed by reflective elements placed on a plane but having a geometry which reproduces an equivalent effect of a spherical or parabolic mirror.

Examples of applications where a Fresnel mirror is used is the case of solar thermodynamic, where mirror having a parabolic section with axial symmetry concentrates light on a tube placed in the mirror focal point.

The synchronous movement of the elements of the Fresnel mirror around an axis, necessary to follow the diurnal motion of the sun in thermodynamic concentration solar systems, can be obtained using the mechanical scheme described in this invention.

Although so far the elements 2 are described as having the features of receivers, they can also act as emitters.

In the case of sound waves, for example, a directional loudspeaker of very large size can be built as a set of many small movable speakers.

The overall speakers support structure, due to its large size, remains fixed, while the beam of sound waves is oriented through the synchronous orientation in a predefined direction of the sound beams emitted from the elements 2.

The synchronous movement of the elements could, for example, be modulated by the music that is transmitted or, in the case of emission of light, by the intensity of light emitted.

1. Tracking system for wave sources comprising
a fixed support panel (1) for the support of
at least one element (2) capable of receiving waves incident from said wave sources,
characterized in that said at least one element (2) is orientable with respect to said fixed panel (1).

2. System according to claim 1 wherein a plurality of elements (2) are synchronously orientable with respect to said fixed panel (1).

3. System according to claim 1 comprising means for determining the orientation suitable for defining the orientation of said at least one orientable element (2).

4. System according to claim 3 wherein said means for determining the orientation comprise sensors means for detecting the direction of the maximum intensity of the incoming wave front.

5. System according to claim 3 wherein said means for determining the orientation comprise means for a pre-planned processing of the panels orientation

6. System according to claim 1 wherein said at least one element (2) is orientable with respect to two axes, a first axis lying in the plane of the support (1) and a second axis being orthogonal to the first.

7. System according to claim 1 comprising tracking means (40, 50) of said wave sources.

8. System according to claim 7 wherein said tracking means (40, 50) comprise orienting means (40) capable of orienting the plurality of elements (2) through supporting rods (3), at the superior end thereof are placed said elements (2), said rods being inferiorly connected to spherical joints (4).

9. System according to claim 8 wherein said spherical joints (4) are housed in holes provided in said fixed panel (1).

10. System according to claim 8 wherein said spherical joints (4) are rotatably associated to said fixed panel (1) through bearings and pairs of ring nuts (5) adjacent to said fixed panel (1), one inferiorly and the other superiorly.

11. System according to claim 10 wherein said ring nuts (5) are mutually constrained by suitable pass through bolts or screws.

12. System according to claim 8 wherein said supporting rods (3) pass through the axes of said spherical joints (4) so that the synchronous rotation of said joints result in a corresponding synchronous orientation of said plurality of elements (2).

13. System according to claim 7 wherein said tracking means (40, 50) comprise moving means (50) capable of making the spherical joints (4) to rotate on their own.

14. System according to claim 13 wherein said moving means (50) comprise two stepper motors for providing a synchronous rotation of said spherical joints (4).

15. System according to claim 1 wherein said plurality of elements (2) comprise photovoltaic elements.

16. System according to claim 1 wherein said plurality of elements (2) comprise a mirror.

17. System according to claim 1 wherein said at least one element (2) of said plurality of elements (2) is capable of being removably associated to one said supporting rod (3).

18. System according to claim 1 wherein said at least one element (2) is removably fastened to said supporting rod (3).

19. System according to claim 1 comprising a bayonet or screw mechanism allowing for the removable interconnection between said elements (2) and said supporting rods (3).

20. Waves emission System comprising
a fixed panel (1) for the support of
at least a waves emitter element
characterized in that at least one element is orientable, with respect to the fixed panel (1), towards a predefined direction of emission.

21. System according to claim 20 wherein a plurality of elements are synchronously orientable with respect to said fixed panel (1), towards a predefined direction of emission.

22. Emission system according to claim 20 wherein the waves emitted comprise sound waves.

23. Emission system according to claim 20 wherein the waves emitted comprise electromagnetic or light waves.

24. System for receiving/emitting waves comprising
a supporting panel for the support of
at least an element capable of receiving or emitting waves
characterized in that said element is removably associated and replaceable in said supporting panel.

25. System according to claim 25 wherein said panel is fixed.

26. System according to claim 25 wherein said panel is orientable.
